(19) United States
(12) Patent Application Publication
(10) Pub. No.: US 2004/0170930 A1
(43) Pub. Date: Sep. 2, 2004

(54) Method of forming a resist pattern and resist pattern forming apparatus

(75) Inventors: Yuuichi Kawaguchi, Tokyo (JP); Hiroaki Takahata, Tokyo (JP); Hisaji Oyake, Tokyo (JP)

Correspondence Address: GREENBLUM & BERNSTEIN, P.L.C., 1950 ROLAND CLARKE PLACE, RESTON, VA, 20191, US

(73) Assignee: TDK Corporation, Tokyo (JP)

(21) Appl. No.: 10/786,006

(22) Filed: Feb. 26, 2004

(30) Foreign Application Priority Data
Feb. 28, 2003 (JP) 2003-052401

(51) Int. Cl. G03F 7/00

(52) U.S. Cl. 430/322; 355/18

(57) ABSTRACT

A resin layer including a benzophenone compound is formed on a surface of a glass substrate, and a photoresist layer is formed on a surface of the resin layer. The photoresist layer is irradiated with a laser beam with a wavelength of 100 nm to 300 nm to form a latent image, and a resist pattern with recessed and protruding parts are formed in the photoresist layer by developing the photoresist layer in which the latent image has been formed.

### BACKGROUND OF THE INVENTION

1. Field of the Invention

This invention relates to a method of forming a resist pattern and a resist pattern forming apparatus that form a resist pattern by irradiating a photoresist layer with an exposure beam.

2. Description of the Related Art

A method of forming a resist pattern that uses photolithography is conventionally known as a method of forming a fine resist pattern on a photoresist layer of a substrate surface as part of a process that manufactures a stamper used in the manufacture of optical recording media, for example. A stamper manufacturing method (as one example, the manufacturing method for a stamper copying disc disclosed in Japanese Laid-Open Patent Publication No. 2000-11465) that manufactures a stamper by forming an electroless nickel layer and an electro nickel layer on the surface of a resist pattern is conventionally known as a method of manufacturing a stamper using a master disc on which a resist pattern has been formed according to the above type of method of forming a resist pattern.

When manufacturing a stamper according to this type of method of forming a resist pattern and stamper manufacturing method, first, as shown in FIG. 12, a photoresist layer 23 is formed by applying a photoresist material, such as novolac resin or polystyrene resin, onto the surface of a glass substrate 21 by spin coating. Next, as shown in FIG. 12, irradiation with a laser beam L with a wavelength of 351 nm, for example, is carried out to expose the photoresist layer 23 and thereby form a latent image in the photoresist layer 23. Next, the photoresist layer 23 in which the latent image has been formed is developed. At this time, as shown in FIG. 13, parts that have been irradiated by the laser beam L are removed, and recessed parts 52a in the shape of a spiral are formed in the photoresist layer 23. By doing so, a master disc 52, which has a resist pattern with protrusions and recesses formed in the photoresist layer 23, is manufactured.

Next, as shown in FIG. 14, by carrying out an electroless nickel plating process, for example, an electroless nickel layer 11 is formed on the surface of the resist pattern in the photoresist layer 23. After this, as shown in FIG. 15, an electroplating process is carried out using the electroless nickel layer 11 as an electrode, thereby forming an electro nickel layer 12 on the electroless nickel layer 11. Next, after the multilayer structure composed of the photoresist layer 23 and the nickel layers 11 and 12 has been stripped from the glass substrate 21, the multilayer structure is soaked in a resist stripper to dissolve the photoresist layer 23. By doing so, as shown in FIG. 16, a stamper 51 composed of the electroless nickel layer 11 and the electro nickel layer 12 is manufactured. In this case, protruding parts 51a are formed in a spiral on the lower surface of the stamper 51.

Next, when a disc substrate D11 (see FIG. 17) for an optical recording medium is manufactured using this stamper 51, the stamper 51 is set inside a mold used for injection molding and resin R is injected as shown in FIG. 17. As a result, as shown in FIG. 18, the protruding parts 51a of the stamper 51 are transferred to the resin R to form guide grooves D11a, thereby manufacturing the disc substrate D11. On the other hand, the recording capacity of optical recording media is increasing every year. Accordingly, to keep up with this, it is necessary to make the width and pitch of the guide grooves D11a formed on the disc substrate D11 narrower. In order to make the width and pitch of the recessed parts 52a in the resist pattern narrower than in conventional patterns, in recent years laser beams L with shorter wavelengths (for example, 300 nm or less) than before have started to be used during the formation of the resist pattern. Here, the shorter the wavelength, the smaller the spot diameter of the laser beam L used to irradiate the photoresist layer 23, so that the width and pitch of the recessed parts 52a in the resist pattern can be made narrower.

However, by investigating the above method of forming a resist pattern, the present inventors discovered the following problem. That is, with the above method of forming a resist pattern, the photoresist layer 23 is formed using a photoresist material, such as novolac resin or polystyrene resin. Such photoresist materials are difficult to expose with a laser beam L with a short wavelength (such as a wavelength between 100 nm and 300 nm inclusive), so that the irradiated laser beam L is attenuated and has problems exposing the photoresist material in a lower periphery (near the surface of the glass substrate 21) of the photoresist layer 23. Accordingly, like a master disc 62 shown in FIG. 19, there are cases where recessed parts 62a that are shallower than a desired depth (the depth shown by the broken lines in FIG. 19) is formed. When disc substrates D12 are manufactured using a stamper 61 (see FIG. 20) that has been manufactured using this kind of master disc 62, as shown in FIG. 20 guide grooves D12a that are shallower than a desired depth (the depth shown by the broken lines in FIG. 20) is formed. The guide grooves of a disc substrate need to be formed with the desired depth so that tracking can be carried out correctly for an optical recording medium. Accordingly, when a resist pattern has been formed using a laser beam L with a short wavelength according to the conventional method of forming a resist pattern, a recessed part that is shallower than the desired depth is formed. When reading and writing of recording data are carried out for an optical recording medium manufactured using this resist pattern, there is the risk that tracking will not be carried out correctly, so that it may not be possible to read and write recording data properly. In this case, it would be conceivable to expose the photoresist layer 23 as far as the bottom by irradiating with a high-intensity laser beam L. However, if this method were used, a wide area would be exposed on the surface side of the photoresist layer 23, so that as shown in FIG. 19, recessed parts 62a with a V-shaped cross-sectional form would be formed, which also results in difficulty in performing tracking correctly. Accordingly, this method is also problematic.

On the other hand, it would be conceivable to use a chemical amplification photoresist material that can be easily exposed by a laser beam L with a short wavelength in place of the novolac resin or the polystyrene resin. The chemical amplification photoresist material can be composed of a polymer, in which a hydroxide group of polyvinylphenol is protected by a t-butoxycarbonyl group, and a PAG (Photo Acid Generator). In this case, when the photoresist layer formed of the chemical amplification photoresist material is exposed by the laser beam L, the exposure of the polymer is assisted by the acid generated due to the action of the PAG, so that it is possible to expose the photoresist layer as far as the bottom using a laser beam L with a short wavelength. However, in the photoresist layer formed of the chemical amplification photoresist material, the acid generated is neutralized over time by ammonia and the like in the atmosphere. The laser beam L is irradiated and successively exposes the entire area of the photoresist layer, and at present several hours are required from the start of exposure to the end of exposure. Since the acid described above is neutralized over time, there is unevenness in the degree of exposure for the photoresist material and the problem that it is difficult to form an even resist pattern. Accordingly, use of a chemical amplification photoresist material is also problematic.

### SUMMARY OF THE INVENTION

The present invention was conceived in view of the above problems and it is a principal object of the present invention to provide a method of forming a resist pattern and a resist pattern forming apparatus that can form a recessed part of a desired depth in a resist pattern by using an exposure beam with a short wavelength.

To achieve the stated object, a method of forming a resist pattern according to the present invention includes steps of forming a resin layer, which includes a benzophenone compound, on a substrate surface, forming a photoresist layer on a surface of the resin layer, forming a latent image by irradiating the photoresist layer with an exposure beam with a wavelength of 100 nm to 300 nm inclusive, and forming a resist pattern with recessed and protruding parts in the photoresist layer by developing the photoresist layer in which the latent image has been formed.

A resist pattern forming apparatus according to the present invention includes a resin layer forming device that forms a resin layer including a benzophenone compound on a substrate surface, a photoresist layer forming device that forms a photoresist layer on a surface of the resin layer, an exposure device that forms a latent image by irradiating the photoresist layer with an exposure beam with a wavelength of 100 nm to 300 nm inclusive, and a developing device that forms a resist pattern with recessed and protruding parts in the photoresist layer by developing the photoresist layer in which the latent image has been formed.

According to this method of forming a resist pattern and this resist pattern forming apparatus, a resin layer including a benzophenone compound is formed on a substrate surface and a photoresist layer formed on a surface of the resin layer is irradiated with an exposure beam with a wavelength of 100 nm to 300 nm inclusive to form a latent image, so that the exposure of the photoresist layer is assisted by a reaction to light and heat by the benzophenone compound. This means that it is possible to reliably expose the photoresist layer, which causes attenuation in the exposure beam, even in a lower periphery of the photoresist layer, and as a result it is possible to reliably form a latent image as far as the bottom of the photoresist layer using an exposure beam with a short wavelength. Accordingly, since it is possible to reliably form a resist pattern with recessed part of the desired depth in the photoresist layer, it is possible to reliably form a protruding part of a desired height in a protruding and recessed pattern when manufacturing a stamper, for example, using this resist pattern. As a result, it is possible to properly form guide grooves with the desired depth when manufacturing a disc substrate for an optical recording medium, for example, using this stamper. Accordingly, when reading and writing recording data onto an optical recording medium that uses this disc substrate, it is possible to reliably avoid difficulties in properly reading and writing the recording data due to tracking difficulties. Also, since it is possible to form a recessed part of a desired depth in a resist pattern using an exposure beam with a lower intensity than in the conventional method of forming a resist pattern, it is possible to prevent the recessed part in a resist pattern from being formed with a V-shaped cross-section.

Here, it is preferable to form the resin layer with a thickness of 100 nm to 200 nm, inclusive and to form the photoresist layer with a thickness of 120 nm to 200 nm, inclusive. By doing so, it is possible to increase the effect of a reaction to light and heat by the resin layer, so that it is possible to reliably form a latent image as far as the bottom of the photoresist layer using an exposure beam with a short wavelength. As a result, it is possible to form a resist pattern with a recessed part of a desired depth more reliably.

It is more preferable to form the photoresist layer with a thickness of 160 nm to 200 nm, inclusive. By doing so, it is possible to further increase the effect of the reaction to light and heat, so that it is possible to more reliably form the latent image as far as the bottom of the photoresist layer. As a result, it is possible to form a resist pattern with a recessed part of the desired depth even more reliably.

It should be noted that the disclosure of the present invention relates to a content of Japanese Patent Application 2003-052401 that was filed on 28 Feb. 2003 and the entire content of which is herein incorporated by reference.

### BRIEF DESCRIPTION OF THE DRAWINGS

These and other objects and features of the present invention will be explained in more detail below with reference to the attached drawings, wherein:

FIG. 1 is a cross-sectional view of a stamper according to an embodiment of the present invention;

FIG. 2 is a cross-sectional view showing a state where a resin layer has been formed on a surface of a glass substrate;

FIG. 3 is a cross-sectional view showing a state where a photoresist layer formed on a surface of the resin layer is irradiated with a laser beam used for exposure;

FIG. 4 is a cross-sectional view of a master disc;

FIG. 5 is a cross-sectional view showing a state where an electroless nickel layer has been formed on the surface of the master disc;

FIG. 6 is a cross-sectional view showing a state where an electro nickel layer has been formed on the electroless nickel layer;

FIG. 7 is a cross-sectional view showing a state where a recessed and protruding pattern of the stamper has been transferred to resin (a disc substrate);

FIG. 8 is a cross-sectional view showing the disc substrate manufactured using the stamper;

FIG. 9 is a block diagram showing the construction of a manufacturing apparatus for a stamper according to an embodiment of the present invention;

FIG. 10 is a table showing respective values of intensity of the laser beam irradiated onto the photoresist layer during the formation of resist patterns and observation results for the formed resist patterns in the first to third embodiments of the present invention;

FIG. 11 is a table showing respective values of intensity of the laser beam irradiated onto the photoresist layer during the formation of resist patterns and observation results for the formed resist patterns in the first to sixth comparative examples related to embodiments of the present invention;

FIG. 12 is a cross-sectional view showing a state where the photoresist layer formed on the surface of a glass substrate is irradiated with a laser beam used for exposure in a conventional manufacturing process for a master disc;

FIG. 13 is a cross-sectional view of the master disc;

FIG. 14 is a cross-sectional view showing a state where the electroless nickel layer has been formed on the surface of the master disc;

FIG. 15 is a cross-sectional view showing a state where the electro nickel layer has been formed (as a layer) on the electroless nickel layer;

FIG. 16 is a cross-sectional view of a conventional stamper;

FIG. 17 is a cross-sectional view showing a state where the protruding and recessed pattern of the stamper has been transferred to resin (a disc substrate);

FIG. 18 is a cross-sectional view showing a conventional disc substrate manufactured using the stamper;

FIG. 19 is a cross-sectional view showing a master disc manufactured according to a conventional manufacturing method; and

FIG. 20 is a cross-sectional view of a stamper manufactured using the master disc and a disc substrate manufactured using the stamper.

### DESCRIPTION OF THE PREFERRED EMBODIMENTS

Hereafter, preferred embodiments of a method of forming a resist pattern and a resist pattern forming apparatus according to the present invention will be described with reference to the attached drawings. It should be noted that component parts that have the same construction as the stamper 51 and the master disc 52 in the method of forming a resist pattern and the resist pattern forming apparatus according to the related art have been assigned the same reference numerals and description thereof is omitted.

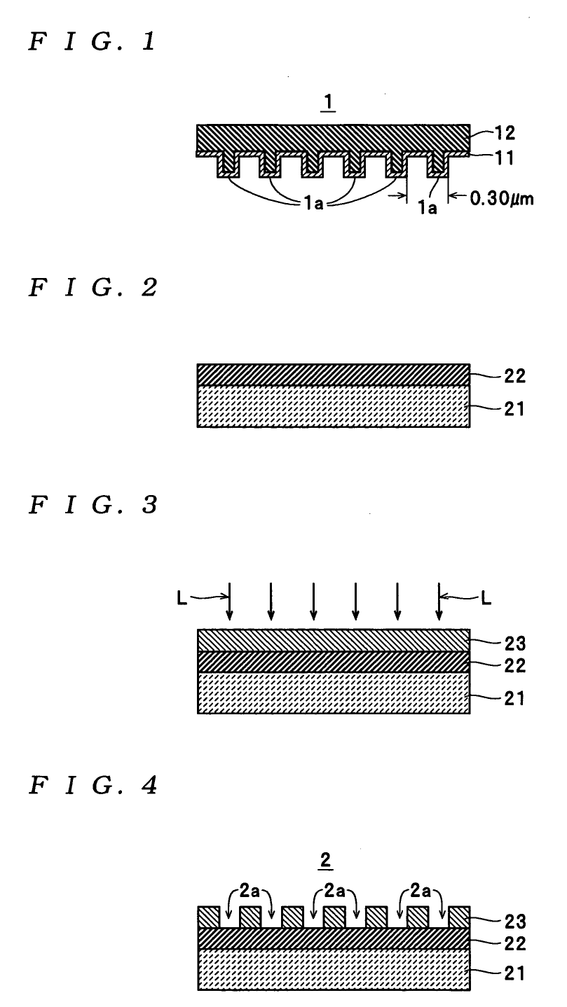

A stamper 1 shown in FIG. 1 is used when manufacturing the disc substrate D1 (see FIG. 8) for an optical recording medium and is manufactured using a master disc 2 (see FIG. 4) on which a resist pattern has been formed according to the method of forming a resist pattern according to the present invention. The stamper 1 is constructed in the overall shape of a plate where the electro nickel layer 12 is formed on top of the electroless nickel layer 11. Fine protruding parts 1a for forming fine guide grooves D1a in a surface of the disc substrate D1 are formed in a spiral on a lower surface of the stamper 1. In this case, the formation pitch of the protruding parts 1a is determined in accordance with the formation pitch of the guide grooves D1a on the disc substrate D1, and can be 0.32 μm, for example.

Next, a manufacturing apparatus 100 that manufactures the stamper 1 will be described with reference to the drawings.

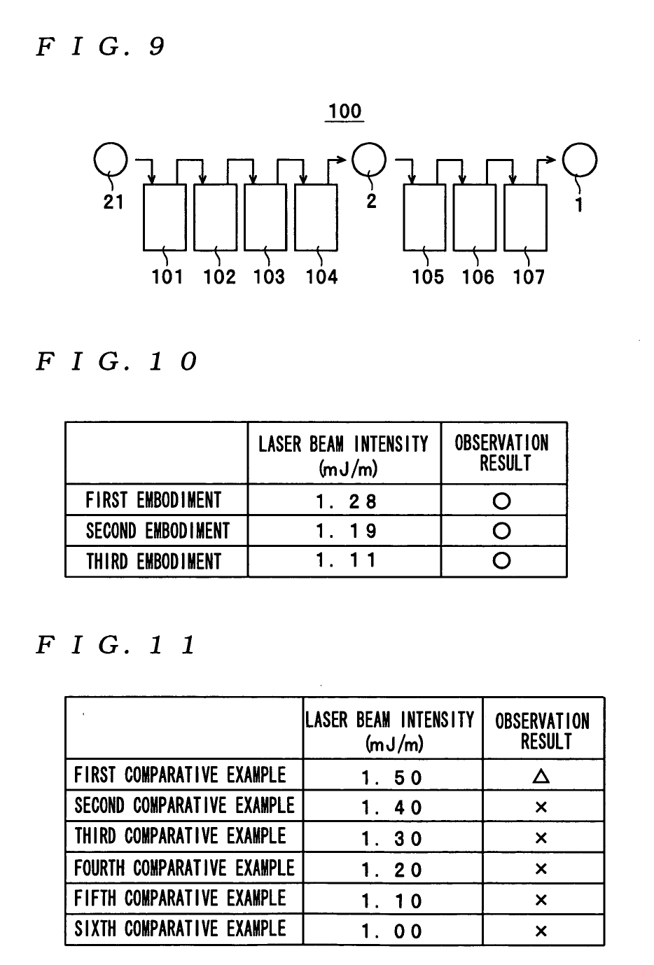

As shown in FIG. 9, the manufacturing apparatus 100 includes a resin layer forming device 101, a photoresist layer forming device 102, an exposure device 103, a developing device 104, a conductive layer applying device 105, a stamper forming material forming device 106, and a stripping device 107. After a resist pattern has been formed according to the method of forming a resist pattern according to the present invention, the stamper 1 is manufactured using the master disc 2 on which this resist pattern has been formed. In this case, the resist pattern forming apparatus according to the present invention is composed of the resin layer forming device 101, the photoresist layer forming device 102, the exposure device 103, and the developing device 104.

As shown in FIG. 2, the resin layer forming device 101 applies an applied liquid for forming a resin layer 22 onto a surface of the glass substrate 21 by spin coating, for example, thereby forming the resin layer 22 in a thin film with a thickness of around 150 nm, for example (an example value in a range of 100 nm to 200 nm inclusive for the present invention). As shown in FIG. 3, the photoresist layer forming device 102 applies a photoresist material onto the surface of the resin layer 22 by spin coating, for example, thereby forming the photoresist layer 23 in a thin film with a thickness of around 160 nm, for example (an example value in a range of 120 nm to 200 nm inclusive for the present invention). Also in FIG. 3, the exposure device 103 exposes the photoresist layer 23 by irradiation with the laser beam L with a wavelength of 266 nm, for example, (an example value in a range of 100 nm to 300 nm inclusive for the present invention) at a predetermined intensity, thereby forming a latent image in the photoresist layer 23.

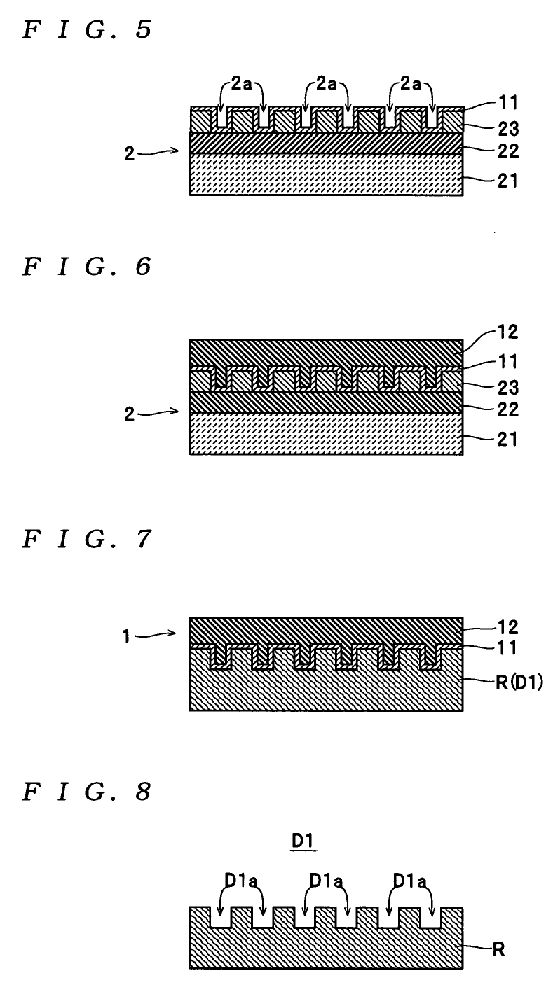

As shown in FIG. 4, the developing device 104 forms recessed parts 2a by developing the photoresist layer 23 in which the latent image has been formed and then removing parts that were irradiated by the laser beam L, thereby forming a resist pattern with protruding and recessed parts in the photoresist layer 23. In this way, the master disc 2 is produced. As shown in FIG. 5, the conductive layer applying device 105 carries out an electroless plating process to form the electroless nickel layer 11 on a surface of the resist pattern in the photoresist layer 23. As shown in FIG. 6, the stamper forming material forming device 106 carries out an electroplating process using the electroless nickel layer 11 as an electrode, thereby forming (as a layer) the electro nickel layer 12 on the electroless nickel layer 11. The stripping device 107 soaks the multilayer structure composed of the resin layer 22, the photoresist layer 23, the electroless nickel layer 11, and the electro nickel layer 12 in an aqueous 20% (by weight) solution of sodium hydroxide, for example, thereby dissolving and removing the resin layer 22 and the photoresist layer 23.

Next, the process for forming the stamper 1, after the resist pattern has been formed in the photoresist layer 23, using the manufacturing apparatus 100 will be described with reference to the drawings.

First, the applied liquid for forming the resin layer 22 is manufactured. This applied liquid is composed of a benzophenone compound, which reacts to light and heat from the laser beam L with a wavelength in a range of 100 nm to 300 nm inclusive, for example, and a thermal hardening resin. In this case, in the present embodiment, 4,4′-bis(diethylamine) benzophenone is used as one example of a benzophenone compound, and a melamine resin produced by combining melamine and formalin or the like is used as the thermal hardening resin. Here, the content of the benzophenone compound in the applied liquid should preferably be set in a range of 10% to 70% inclusive by weight relative to the applied liquid. The present inventors confirmed through experimentation that when the content is below this range, the applied liquid reacts insufficiently to light and heat, while when the content exceeds this range, the formed resin layer 22 is insufficiently strong. It should be noted that it is possible to use 4,4′-bis (dimethylamine) benzophenone in place of the 4,4′-bis(diethylamine) benzophenone. In addition, it is possible to use a UV hardening resin in place of the melamine resin. Also, to improve adhesion with the photoresist layer 23 that is formed later, an auxiliary adhesive agent, a surfactant, or other type of additive may be added during the manufacture of the applied liquid.

Next, the manufactured applied liquid is stored inside the resin layer forming device 101. Next, the resin layer forming device 101 forms the resin layer 22 on the surface of the glass substrate 21. More specifically, the resin layer forming device 101 forms a layer of a coupling agent (not shown) on the surface of the glass substrate 21 after the surface has been ground flat, and then applies the applied liquid onto the surface of the glass substrate 21 by spin coating. In this case, the resin layer forming device 101 adjusts the applied amount of applied liquid and the rpm used during spin coating so that the resin layer 22 is formed with a thickness of around 150 nm, for example. After this, the resin layer forming device 101 hardens the applied film by heat treating the glass substrate 21 in this state. By doing so, as shown in FIG. 2, a resin layer 22 with a thickness of around 150 nm is formed on the surface of the glass substrate 21. It should be noted that in the case where a UV hardening resin is used during the manufacture of the applied liquid, the resin layer forming device 101 hardens the applied liquid by irradiation with UV rays for hardening the applied liquid after application. Next, the photoresist layer forming device 102 spin coats the surface of the resin layer 22 with a photoresist material (for example, DVR100 manufactured by ZEON CORPORATION of Japan). In this case, the photoresist layer forming device 102 adjusts the applied amount of photoresist material and the rpm used during spin coating so that the photoresist layer 23 is formed with a thickness of around 160 nm, for example. Next, the photoresist layer forming device 102 causes any remaining solvent in the photoresist material to evaporate by baking. By doing so, as shown in FIG. 3, the photoresist layer 23 is formed with a thickness of around 160 nm on the surface of the resin layer 22.

Next, the exposure device 103 irradiates parts of the photoresist layer 23 where the recessed parts 2a are to be formed with the laser beam L that has a wavelength of 266 nm and an intensity of 1.28 mJ/m as the first embodiment (see FIG. 10). By doing so, a spiral latent image that is around 0.15 μm wide and has a pitch of around 0.32 μm, for example, is formed in the photoresist layer 23. At this time, the benzophenone compound included in the resin layer 22 reacts to the light and heat provided by the irradiating laser beam L and thereby assists the exposure reaction of the photoresist material in a lower periphery of the photoresist layer 23. This means that even the photoresist material in the lower periphery of the photoresist layer 23, which causes attenuation in the laser beam L, can be reliably exposed, resulting in the latent image being reliably formed as far as the bottom of the photoresist layer 23. Next, the photoresist layer 23 in this state is developed by the developing device 104. As shown in FIG. 4, by doing so the parts irradiated by the laser beam L are removed and the recessed parts 2a are formed, resulting in the master disc 2 being manufactured. In this case, the latent image is reliably formed as far as the bottom of the photoresist layer 23, so that the recessed parts 2a can be properly formed with the desired depth.

Next, as shown in FIG. 5, the conductive layer applying device 105 carries out an electroless plating process to form a conductive electroless nickel layer 11 (conductive layer) on the surface of the resist pattern in the photoresist layer 23. By doing so, the surface of the photoresist layer 23 is made conductive. In this case, the material used for forming the conductive layer that makes the surface of the photoresist layer 23 conductive is not limited to nickel, and a variety of metal materials can be used. The method of forming the conductive layer is not limited to an electroless plating process, and it is possible to form a layer of various metal materials (such as a nickel layer) by various methods such as vapor deposition or sputtering. Next, the stamper forming material forming device 106 carries out an electro plating process using the electroless nickel layer 11 as an electrode, so that as shown in FIG. 6, the electro nickel layer 12 is formed (as a layer) on the electroless nickel layer 11. In this case, the multilayer structure composed of the electroless nickel layer 11 and the electro nickel layer 12 (also referred to as the “stamper multilayer structure”) constructs the stamper 1.

Next, after the stripping device 107 has stripped the glass substrate 21 from the master disc 2 on which the stamper multilayer structure is formed, the multilayer structure composed of the resin layer 22, the photoresist layer 23, and the stamper multilayer structure is soaked in a 20% (by weight) aqueous solution of sodium hydroxide to dissolve and remove the photoresist layer 23. At this time, since the aqueous sodium hydroxide solution is more alkaline than a normal photoresist stripping agent, the photoresist layer 23 can be reliably dissolved in a short time (for example, around three minutes) together with the resin layer 22. By doing so, as shown in FIG. 1, the stamper 1 is manufactured. In this case, the recessed parts 2a of the resist pattern formed in the photoresist layer 23 are formed with the desired depth, so that the protruding parts la of the stamper 1 are properly formed with the desired height (protruding distance).

Next, when the manufactured stamper 1 is used to manufacture the disc substrate D1 for an optical disc recording medium, as shown in FIG. 7, after the stamper 1 has been set in a mold used for injection molding, resin R is injected. By doing so, as shown in FIG. 8, the protruding parts 1a of the stamper 1 are transferred to the resin R to form the guide grooves D1a, thereby manufacturing the disc substrate D1. In this case, since the protruding parts 1a of the stamper 1 have been formed with the desired height, the guide grooves D1a are correctly formed with the desired (required) depth. Accordingly, for an optical recording medium that uses the disc substrate D1, it is possible to reliably avoid problems relating to the proper reading and writing of recording data caused by tracking difficulties.

It should be noted that in a second and a third embodiment of the present invention, the intensity of the 266 nm laser beam L that is emitted from the exposure device 103 is set at respective values shown in FIG. 10. Resist patterns were formed according to the process described above, and the formed states of the recessed parts 2a of the respective resist patterns were observed using a scanning electron microscope. As a result, as shown in FIG. 10, in the second and third embodiments, the recessed parts 2a are correctly formed with the desired depth. On the other hand, although an observation result is not shown, when the laser beam L is irradiated at an intensity of 1.00 mJ/m or below, the low intensity results in slightly shallow recessed parts 2a being formed. It should be noted that in FIG. 10, observation results where the recessed parts 2a were correctly formed with the desired depth are marked with circles.

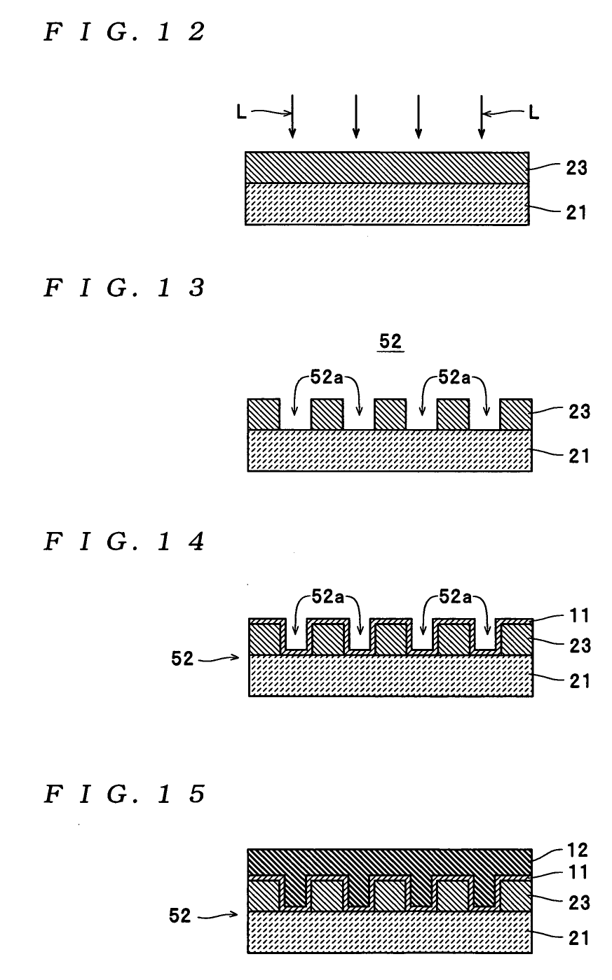

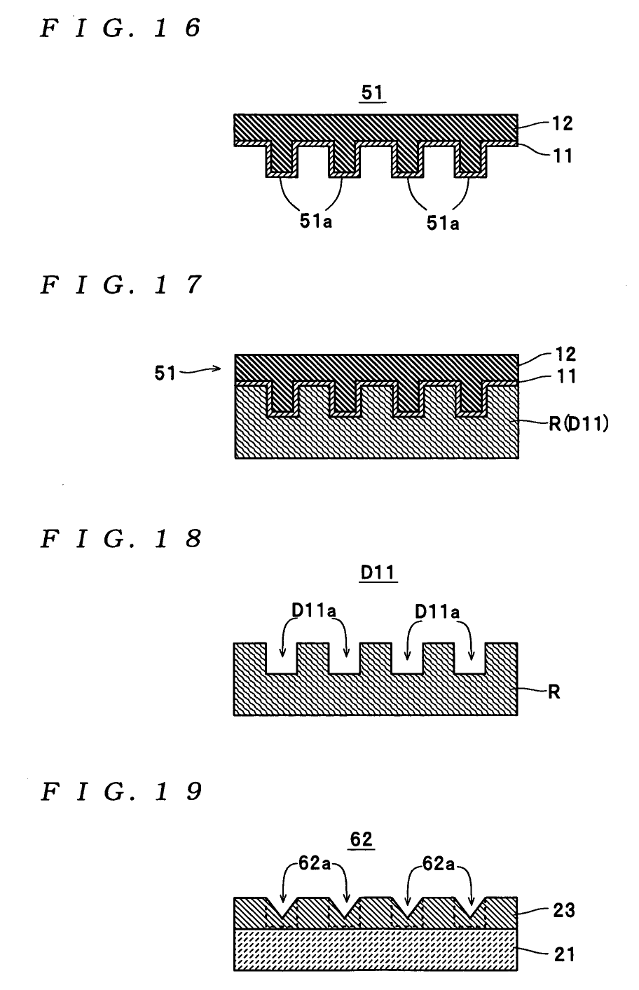

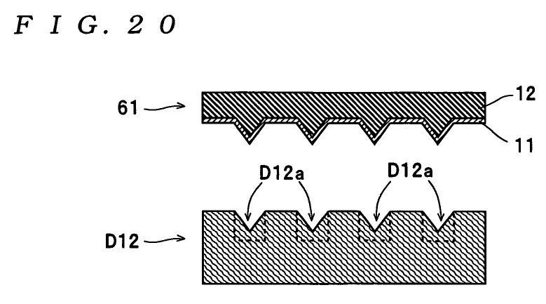

Also, a photoresist layer 23 with a thickness of 160 nm (the same thickness as the first to third embodiments) was formed on a glass substrate 21 on which the resin layer 22 has not been formed, a 266 nm laser beam L was irradiated with the intensity of the laser beam L set at the respective values of first to sixth comparative examples shown in FIG. 11 to form resist patterns, and the respective resist patterns were observed in the same way as above. As a result, while the recessed parts 2a were formed with the desired depth in the first comparative example, the recessed parts 2a were V-shaped in cross-section. On the other hand, in the second to sixth comparative examples, the recessed parts 2a were formed shallower than the desired depth. It should be noted that in FIG. 11, a triangle indicates that the recessed part 2a were formed with the desired depth but was otherwise not preferable, while crosses indicate that the recessed parts 2a were formed with a depth outside the tolerated range. From the above results, it is clear that by forming the resin layer 22 between the glass substrate 21 and the photoresist layer 23, the recessed parts 2a can be properly formed with the desired depth by irradiation with the laser beam L at a low intensity compared to the conventional method of forming a resist pattern in which the resin layer 22 is not formed.

In this way, according to this method of forming a resist pattern and the manufacturing apparatus 100, the resin layer 22 that includes a benzophenone compound is formed on the surface of the glass substance 21 and by forming a latent image by irradiating a photoresist layer 23 formed on the surface of the resin layer 22 with the 266 nm laser beam L, the reaction of the benzophenone compound to the light and heat can assist the exposure of the photoresist material. This means that the photoresist material can be reliably exposed even at the lower periphery of the photoresist layer 23 that causes attenuation in the laser beam L, resulting in it being possible to reliably form a latent image as far as the bottom of the photoresist layer 23 using an exposure beam with a short wavelength. Accordingly, since it is possible to properly form the recessed parts 2a with the desired depth in the photoresist layer 23, it is possible to properly form the protruding parts 1a with the desired height on the stamper 1. As a result, since it is possible to properly form guide grooves D1a of the desired depth in the disc substrate D1, when recording data is read from or written onto an optical recording medium produced using the disc substrate D1, it is possible to avoid difficulties in properly reading and writing the recording data due to tracking difficulties. Also, since the recessed parts 2a of the desired depth are formed using the laser beam L that has lower intensity than the conventional method of forming a resist pattern, it is possible to prevent the recessed parts 2a from being formed with a V-shaped cross-sectional form.

It should be noted that the present invention is not limited to the embodiments described above, and although an example of where a stamper for optical recording media is manufactured has been described in the above embodiments, a resist pattern formed according to this method of forming a resist pattern can be used when manufacturing a semiconductor element or when manufacturing a stamper for manufacturing discrete track-type recording media, on which a large number of concentric data recording tracks that are separated by a predetermined arrangement pitch are formed. Also, the additive that is added to the applied liquid for forming the resin layer 22 is not limited to 4,4′-bis(diethylamine) benzophenone and 4,4′-bis(dimethylamine) benzophenone, and other benzophenone compounds may be used.

The thickness of the resin layer 22 is not limited to 150 nm, and can be set at a freely chosen value. The thickness of the photoresist layer 23 is not limited to 160 nm and can also be set at a freely chosen value. In this case, it is preferable for the thickness of the resin layer 22 to be 100 nm to 200 nm inclusive and for the thickness of the photoresist layer 23 to be 120 nm to 200 nm inclusive. The present inventors confirmed through experimentation that when the resin layer 22 is formed with a thickness in a range of 100 nm to 200 nm inclusive, and the photoresist layer 23 is formed with a thickness in a range of 120 nm to 200 nm inclusive, if irradiation is carried out with a 266 nm laser beam L, the effect of the resin layer 22 reacting to the light and heat is prominent and the latent image is reliably formed as far as the bottom of the photoresist layer 23. The present inventors also confirmed through experimentation that when the thickness of the photoresist layer 23 is set in a range of 160 nm to 200 nm inclusive, the effect of the reaction to light and heat is even more prominent.

What is claimed is:

1. A method of forming a resist pattern comprising steps of:
forming a resin layer, which includes a benzophenone compound, on a substrate surface;
forming a photoresist layer on a surface of the resin layer;
forming a latent image by irradiating the photoresist layer with an exposure beam with a wavelength of 100 nm to 300 nm inclusive; and
forming a resist pattern with recessed and protruding parts in the photoresist layer by developing the photoresist layer in which the latent image has been formed.

2. A method of forming a resist pattern according to claim 1, wherein the resin layer is formed with a thickness of 100 nm to 200 nm inclusive and the photoresist layer is formed with a thickness of 120 nm to 200 nm inclusive.

3. A method of forming a resist pattern according to claim 2, wherein the photoresist layer is formed with a thickness of 160 nm to 200 nm inclusive.

4. A resist pattern forming apparatus, comprising:
a resin layer forming device that forms a resin layer including a benzophenone compound on a substrate surface;
a photoresist layer forming device that forms a photoresist layer on a surface of the resin layer;
an exposure device that forms a latent image by irradiating the photoresist layer with an exposure beam with a wavelength of 100 nm to 300 nm inclusive; and a developing device that forms a resist pattern with recessed and protruding parts in the photoresist layer by developing the photoresist layer in which the latent image has been formed.
